(19) United States
(12) Patent Application Publication
(10) Pub. No.: US 2025/0234782 A1
(43) Pub. Date: Jul. 17, 2025

(54) MODULAR PACKAGE ON PACKAGE (POP) THERMOELECTRIC SUBASSEMBLIES FOR THERMO ELECTRIC GENERATOR DEVICES

(71) Applicant: ATS IP, LLC, Fort Collins, CO (US)

(72) Inventors: Ion BASA, Fort Collins, CO (US); Jake PEREZ, Fort Collins, CO (US); John NEWMAN, Fort Collins, CO (US)

(21) Appl. No.: 18/850,284

(22) PCT Filed: Mar. 27, 2023
(86) PCT No.: PCT/US2023/016380

§ 371 Date: Sep. 24, 2024

Related U.S. Application Data
(60) Provisional application No. 63/326,697, filed on Apr. 1, 2022.

(51) Int. Cl. H10N 10/17; H10N 10/01

(52) U.S. Cl. CPC H10N 10/17; H10N 10/01

(57) ABSTRACT

The embodiments herein provide for thermoelectric generators (TEGs) with low coefficients of thermal expansion. In one embodiment, a TEG includes a hot-side substrate comprising a plurality of solder pads. Each solder pad having a p-type semiconductor pellet and an n-type semiconductor pellet affixed thereto. The TEG also includes a cold-side substrate comprising a corresponding plurality of solder pads dimensioned and arranged according to the plurality of solder pads of the hot-side substrate. The corresponding plurality of solder pads of the cold-side substrate is affixed to the hot-side substrate at locations of the plurality of solder pads of the hot-side substrate.

### CROSS REFERENCE TO RELATED APPLICATIONS

This patent application claims priority to, and thus the benefit of an earlier filing date from, U.S. Provisional Patent Application No. 63/326,697 (filed Apr. 1, 2022), the contents of which are hereby incorporated by reference.

### BACKGROUND

Current manufactured thermoelectric generators (TEGs) have size restrictions due to mechanical limitations of thermal expansion. For example, TEG devices are used to produce power from heat (e.g., waste heat), and have two sides-a hot side, and a cold side. The hot side of the device is exposed to a heat source, and the cold side of the device is a cold sink. Some TEGs can produce power at room temperature, whereas others can produce power at temperatures in as excess of 750° C. and anywhere in between. This large temperature differential between the cold side and hot side can induce mechanical stress on the TEG, primarily from thermal expansion. This stress typically limits the physical dimensions of the TEG packaging, as well as the element size, shape, and number of P-N junctions.

### SUMMARY

Systems and methods presented herein provide for thermoelectric generators (TEGs) with low coefficients of thermal expansion. In one embodiment, a TEG includes a hot-side substrate comprising a plurality of solder pads. Each solder pad has a p-type semiconductor pellet and an n-type semiconductor pellet affixed thereto. The TEG also includes a cold-side substrate comprising a corresponding plurality of solder pads dimensioned and arranged according to the plurality of solder pads of the hot-side substrate. The corresponding plurality of solder pads of the cold-side substrate is affixed to the hot-side substrate at locations of the plurality of solder pads of the hot-side substrate.

### BRIEF DESCRIPTION OF THE DRAWINGS

Some embodiments of the present invention are now described, by way of example only, and with reference to the accompanying drawings. The same reference number represents the same element or the same type of element on all drawings.

FIG. 1A illustrates one exemplary hot side of a TEG.

FIG. 1B illustrates one exemplary cold side of the TEG.

FIG. 2 is a flowchart of an exemplary process for manufacturing the TEG of FIG. 1.

FIG. 3 is a schematic view of an exemplary cold side substrate configured to affix four TEG cartridges.

FIG. 4 is a perspective view of the TEG of FIG. 3.

FIG. 5 is a perspective view of an exemplary TEG having four TEG cartridges with their hot side substrates affixed to the cold side substrate.

FIG. 6 is a block diagram of an exemplary side view of a TEG.

### DETAILED DESCRIPTION

The figures and the following description illustrate specific exemplary embodiments. It will thus be appreciated that those skilled in the art will be able to devise various arrangements that, although not explicitly described or shown herein, embody certain principles and are included within the scope of the embodiments. Furthermore, any examples described herein are intended to aid in understanding the embodiments and are to be construed as being without limitation to such specifically recited examples and conditions. As a result, the embodiments are not limited to any of the examples described below.

To overcome current limitations on TEG size, shape, and manufacturing, a new Package on Package (POP) method of manufacturing TEGs is proposed. In these embodiments, TEG cartridges are manufactured using multiple modular subassemblies built on a larger substrate. The substrate can be customized to fit consumer needs while adding the necessary number of POP subassemblies in a modular fashion.

Each PoP subassembly is built with a low Coefficient of Thermal Expansion (CTE) material, such as ceramics like aluminum nitride or aluminum oxide with integrated circuits. This subassembly is manufactured by bonding P and N junctions onto the low CTE substrate. Processing and manufacturing of these subassemblies form the building blocks of a modular POP cartridge that minimizes the effect of the coefficient of thermal expansion.

Once POP subassemblies are manufactured, they can be bonded on a larger substrate. Substrates used for this purpose include copper clad alumina (CCA), anodized aluminum with bonded copper interconnects, or other highly conductive substrates such as aluminum PCBs (Printed Circuit Boards). Substrates can vary in geometry from the POP subassembly with relative surface areas as small as two times the size of the POP subassembly to as large as ten times the size of the POP subassembly. The method of manufacturing for the POP cartridge allows for electrical bridging of POP subassemblies to occur on the larger substrate while leaving mechanical gaps between the POP subassemblies. These gaps are designed with the intent of providing room for expansion from CTE effects as well as minimizing the surface area that CTE is exerted on. This minimization in CTE is caused by the smaller POP subassembly surface area, where CTE effects are decoupled by the number of submodules. For example. Eq. 1 illustrates the area thermal expansion of a substrate, and Eq. 2 illustrates the area thermal expansion of a POP relative to the substrate.

$$Δ A = γ {A}_{0} Δ T , \qquad Eq . 1$$

$$and$$

$$Δ A = γ \frac{1}{n} {A}_{0} Δ T , \qquad Eq . 2$$

where γ is the coefficient of area expansion, A₀ is initial area of the object, ΔA is area change of the object, ΔT is the temperature change of the object, and n is the number of PoPs bonded to substrate. Depending on the final cartridge size and power output requirements, a combination of multiple POP subassemblies can be used as a modular building block for large scale TEG assemblies.

The POP cartridge advantages go further than upscaling. The modularity of the design and manufacturing techniques allow for integrated customization of parallel and series connections between subassemblies. This allows for optimization of electrical power output characteristics for each system without having to modify external wiring. Each POP cartridge has inter-integrated circuitry for additional monitoring of power output, fault conditions, and temperature measurements via add in circuitry. This added functionality can be leveraged for large scale operation in the commercial sector. These add in circuitry functions are built with modular device to device interconnects, which are not present on any commercially available TEGs.

In the embodiments herein, thermoelectric cartridges are manufactured using PoP subassemblies to overcome limitations on TEG size and shape, such as those due to thermal expansion. Some POP cartridge manufacturing allows for inherent integration of series and parallel connections. And some POP cartridge manufacturing allows for integration of electronics on a TEG cartridge.

In some embodiments, when the hot sides are separated in size from the cold side, the hot sides negate issues of thermal expansion because the top/hot sides are smaller in size than the bottom/cold side. The top/hot side size stays relatively square at a fraction of the cold side's size. This also has the advantage of the hot side packaging being modular for a “plug and play” aspect with the cold side. This design's manufacturing methodology allows for integrated circuitry and connections, which has never been seen in thermoelectric manufacturing.

The POP Cartridges described herein may be designed, dimensioned, and/or arranged in a variety of ways as a matter of design choice. Some exemplary embodiments and their dimensions are shown and described in the following figures.

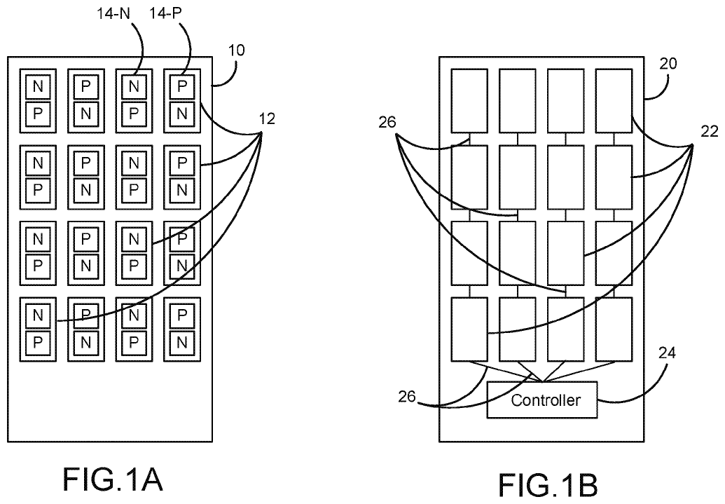

FIG. 1A illustrates one exemplary hot side substrate 10 of a TEG. In this embodiment, the substrate 10 is configured with a plurality of solder pads 12. The solder pads 12 are used to affix p-type and n-type thermoelectric semiconductors 14 to the substrate 10. Each solder pad 12 is configured to affix one p-type thermoelectric semiconductor 14-P and one n-type thermoelectric semiconductor 14-N to the substrate 10. Thus, each solder pad 12 affixes two thermoelectric semiconductors 14 to the substrate 10.

FIG. 1B illustrates one exemplary cold side substrate 20 of the TEG. In this embodiment, the substrate 20 generally has the same dimensions as the substrate 10. The substrate 20 is configured with a plurality of solder pads 22. And the solder pads 22 are dimensioned and arranged in accordance with the solder pads 12 of the hot side substrate 10. Thus, when the TEG is manufactured, the cold side substrate 20 can be affixed to the hot side substrate 10 such that the solder pads 22 “sandwich” the p-type thermoelectric semiconductors 14-P and the n-type thermoelectric semiconductors 14-N at corresponding locations. Thus, the p-type thermoelectric semiconductors 14-P and the n-type thermoelectric semiconductors 14-N at each solder pad 12/22 operate as thermoelectric devices on the PCB hot side substrate 10.

This embodiment illustrates how a TEG can be configured as thermoelectric “cartridges” with lower CTE's so as to provide a lower overall CTE to a TEG. In some embodiments, a controller 24 is mounted on the substrate 20 to monitor features such as a power output, a fault condition, and a temperature measurement of the individual thermoelectric devices, the cartridge, and/or the TEG in general. To implement such, one or more of the solder pads may be electrically coupled to other solder pads on the substrate. For example, in this embodiment, the solder pads 22 of the substrate 20 are coupled in series and to the controller 24 the of circuit lines 26. As such, the substrate 20 may be configured as a PCB. Generally, the controller 24 and the circuit lines 26 are configured with the substrate 20 as the substrate 20 operates as the cold side of the thermoelectric cartridge such that the controller 24 is less susceptible to damage from heat applied to the hot side substrate 10.

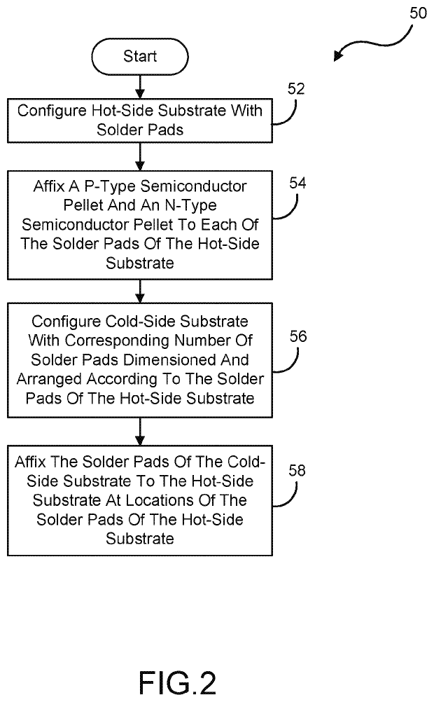

FIG. 2 is a flowchart of an exemplary process 50 for manufacturing the TEG of FIG. 1. In this embodiment, the process 50 initiates when a hot side substrate 10 is configured with a plurality of solder pads 12, in the process element 52. For example, the hot side substrate 10 may be a PCB upon which the solder pads 12 are printed. Then, a p-type semiconductor pellet 14-P and an n-type semiconductor pellet 14-N are affixed to each of the solder pads of the hot side substrate, in the process element 54. Thus, there are two semiconductor pellets 14 affixed to any given solder pad 12. Such may be implemented with a “pick and place” machine used in the electronics industry to affix circuitry to PCBs. In some embodiments, the p-type semiconductor pellets 14-P and the n-type semiconductor pellets 14-N are configured together as a package for individual placement on the solder pads 12. That is, one p-type semiconductor pellet 14-P and one n-type semiconductor pellets 14-N may be configured together as a single package such that the pick and place machine may ensure that each solder pad has one p-type semiconductor pellet 14-P and one n-type semiconductor pellets 14-N affixed thereto.

As mentioned above, the solder pads 12 may be placed on the hot side substrate 10 in a manner that lowers the CTE of the substrate 10. This hot side substrate 10 with the p-type semiconductor pellets 14-P and the n-type semiconductor pellets 14-N affixed thereto forms the basis of a TEG cartridge. The cold side substrate 20 is configured with a corresponding number of solder pads 22 dimensioned and arranged according to the solder pads 12 of the hot side substrate 10, in the process element 56. Then, the solder pads 22 of the cold side substrate 20 are affixed to the hot side substrate 10 at locations of the solder pads 12 of the hot side substrate, in the process element 58.

In some embodiments, the cold side substrate 20 is significantly larger and capable of having a plurality of TEG cartridges affixed thereto. Examples of such are shown and described below.

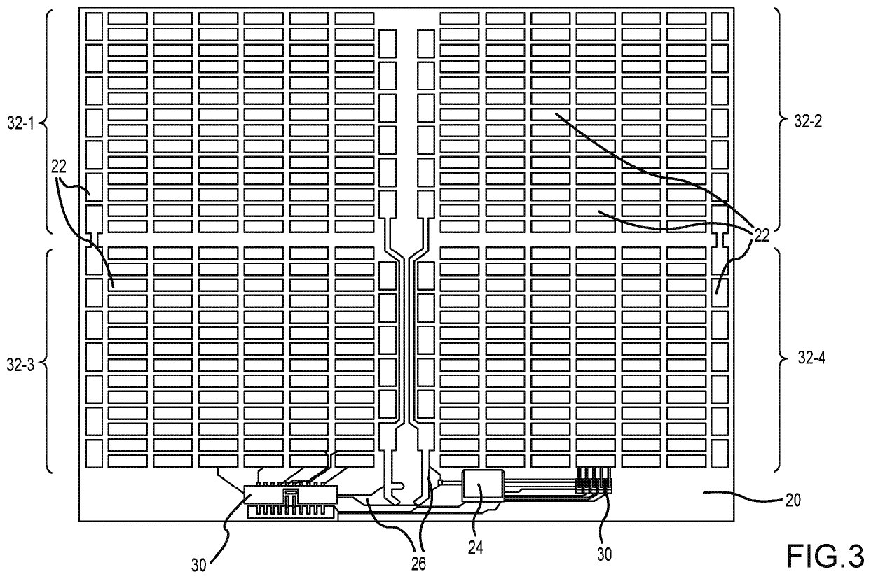

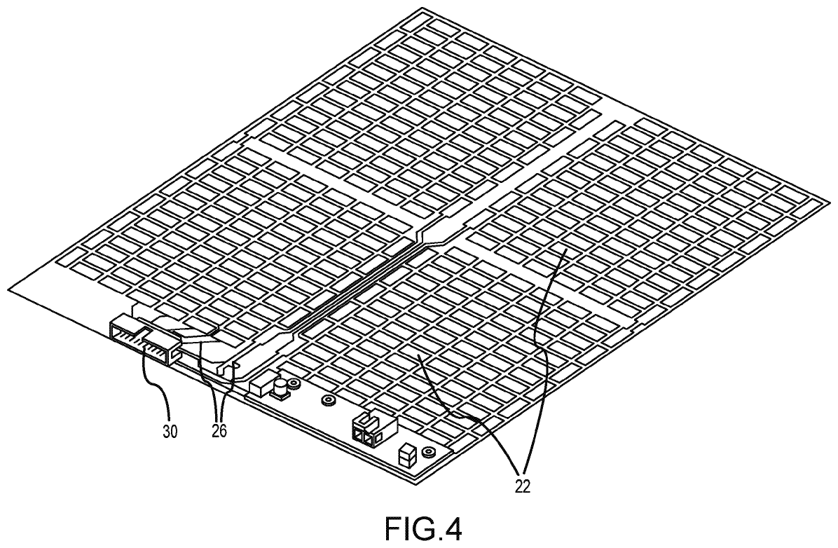

FIG. 3 is a schematic view of an exemplary cold side substrate configured to affix four TEG cartridges. In this embodiment, the cold side substrate 20 has four regions 32-1-32-4 to which TEG cartridges are affixed. As can be seen in this embodiment, the cold side substrate 20 is configured as a PCB with a controller 24, circuit traces 26, and pin connectors 30. This configuration allows for a more modular form of TEG manufacturing while also providing circuitry to monitor certain features of the TEG, such as power output, power faults, etc. Thus, the embodiments herein provide for the manufacture of a TEG with a lower CTE (e.g., due to solder pad spacing) in a more assembly-line approach. That is, a PCB may be configured with the solder pads and circuit lines such that the PCB may enter into a pick and place machine which places components, such as the p-type semiconductor pellets 14-P and the n-type semiconductor pellets 14-N, the controller 24, the pin connectors 30, etc., onto the PCB for rapid manufacture. FIG. 4 is a perspective view of the TEG of FIG. 3.

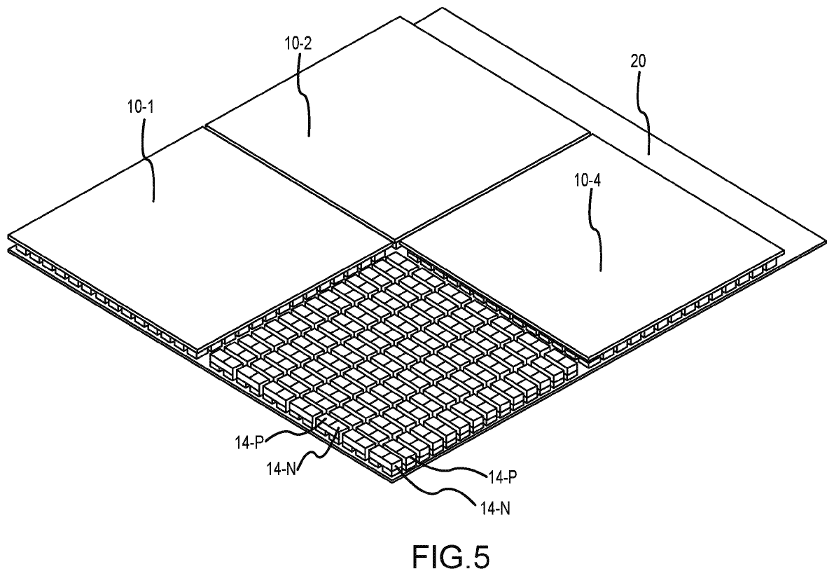

FIG. 5 is a perspective view of an exemplary TEG having four TEG cartridges with their hot side substrates 10 affixed to the cold side substrate 20. In this view, one of the hot side substrates 10 is not shown so as to reveal the p-type semiconductor pellets 14-P and the n-type semiconductor pellets 14-N affixed to the cold side substrate 20. But, in this embodiment, there would be four TEG cartridges with hot side substrates 10-1-10-4 affixed to the larger cold side substrate 20. The embodiment, however, is not intended to be limiting. Rather, a cold side substrate 20 may be configured to hold more TEG cartridges or fewer TEG cartridges than that which is shown herein, as such may be a matter of design choice.

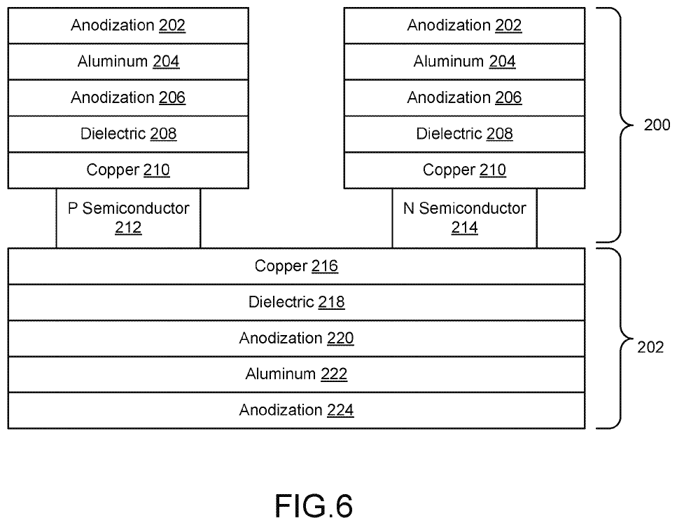

FIG. 6 is a block diagram of an exemplary side view of a TEG. In this embodiment, individual semiconductor components 212 and 214 may be configured as packages 200 for use in a pick and place machine in a PCB manufacturing process. Each package 200 may be the basis of a thermoelectric device having an anodized aluminum layer 204 (i.e., sandwiched between by anodization layers 202 and 206) functioning as a PCB. A dielectric 208 may be configured on the anodization layer 206, and a copper layer 210 may be metallized on top of a semiconductor pellet 214. These components may be affixed to solder pads 12 on the PCB to form the hot side substrate 10. The cold side substrate 20 may be configured as a PCB that has been configured from an anodized aluminum layer 222 (i.e., sandwiched between anodization layers 220 and 224), a dielectric layer 218, and a copper layer that is been metallized onto the dielectric 218.

The anodization layers 220 and 224 provide a high voltage electrical resistance to prevent shorting of the metalized copper layer 210. During heating and cooling cycles that arc expected in a TEG cartridge lifespan, crazing to the anodization layer may occur. Crazing is the micro-fracturing of the anodization layers due to heating and cooling cycles caused by the thermal expansion and internal stress. The dielectric layer 222 is a layer that is also an electrical insulator, but has been formulated to expand and contract with the thermal expansion and thermal cycling of the TEG cartridge. The dielectric layer 222 fills any voids caused by crazing of the anodized layers, and thus prevents shorting of the copper traces and pellets.

Any of the above embodiments herein may be rearranged and/or combined with other embodiments. Accordingly, the concepts herein are not to be limited to any particular embodiment disclosed herein.

What is claimed is:

1. A thermoelectric generator (TEG), comprising:
a hot-side substrate comprising a plurality of solder pads, with each solder pad having a p-type semiconductor pellet and an n-type semiconductor pellet affixed thereto; and
a cold-side substrate comprising a corresponding plurality of solder pads dimensioned and arranged according to the plurality of solder pads of the hot-side substrate, wherein the corresponding plurality of solder pads of the cold-side substrate is affixed to the hot-side substrate at locations of the plurality of solder pads of the hot-side substrate.

2. The TEG of claim 1, further comprising:
a controller affixed to the cold-side substrate and operable to monitor at least one of a power output, a fault condition, and a temperature measurement of the TEG.

3. The TEG of claim 1, wherein:
the hot-side substrate forms a first cartridge of the TEG; and
the TEG further comprises a plurality of cartridges, each configured as the first cartridge and affixed to other locations of the cold side substrate.

4. The TEG of claim 3, wherein:
the cold side substrate comprises at least one circuit trace connecting at least two of the cartridges.

5. The TEG of claim 3, wherein:
each of the cartridges are separated on the cold side substrate to reduce thermal expansion.

6. The TEG of claim 1, wherein:
the plurality of solder pads of the hot-side substrate arc dimensioned and arranged to reduce thermal expansion.

7. A method of manufacturing a thermoelectric generator (TEG), comprising:
configuring a hot-side substrate with a plurality of solder pads;
affixing a p-type semiconductor pellet and an n-type semiconductor pellet to each of the solder pads of the hot-side substrate;
configuring a cold-side substrate with a corresponding plurality of solder pads dimensioned and arranged according to the plurality of solder pads of the hot-side substrate; and
affixing the corresponding plurality of solder pads of the cold-side substrate to the hot-side substrate at locations of the plurality of solder pads of the hot-side substrate to affix the cold-side substrate to the hot-side substrate.

8. The method of claim 7, further comprising:
affixing a controller to the cold-side substrate to monitor at least one of a power output, a fault condition, and a temperature measurement of the TEG.

9. The method of claim 8, further comprising:
forming a plurality of TEG cartridges, each cartridge being configured as the hot-side substrate; and
affixing the TEG cartridges at other locations of the cold side substrate.

10. The method of claim 9, further comprising
forming one or more circuit traces on the cold-side substrate to couple the controller to the cartridges.

11. The method of claim 9, further comprising:
separating the TEG cartridges from one another to provide for thermal expansion.

12. The method of claim 1, further comprising:
dimensioning and arranging the plurality of solder pads of the hot-side substrate to reduce thermal expansion.
